(19) United States
(12) Patent Application Publication
(10) Pub. No.: US 2026/0276600 A1
(43) Pub. Date: Sep. 17, 2026

(54) ACOUSTIC TRANSDUCER ASSEMBLY WITH MOLDED INTERCONNECT DEVICE (MID)

(71) Applicant: Evident Scientific, Inc., Waltham, MA (US)

(72) Inventor: Ronald Kellner, Port Matilda, PA (US)

(21) Appl. No.: 19/168,734

(22) PCT Filed: Mar. 26, 2024
(86) PCT No.: PCT/US2024/021527

§ 371 Date: Sep. 24, 2025

Related U.S. Application Data
(60) Provisional application No. 63/456,159, filed on Mar. 31, 2023.

(51) Int. Cl. G01N 29/24; G01N 29/04; G01N 29/28; H04R 17/00; H04R 31/00

(52) U.S. Cl. CPC G01N 29/2437; G01N 29/04; G01N 29/28; H04R 17/00; H04R 31/006; G01N 2291/023; G01N 2291/101

(57) ABSTRACT

An acoustic transducer assembly can be fabricated using a molded interconnect device (MID) approach. For example, respective conductive interconnections can be formed on an interior surface of a cavity defined by a molded dielectric housing. A piezoelectric element can be arranged within the cavity and fed electrically by the formed conductive interconnections. A backing material can be established within the cavity, such as filled and cured. A portion, such as a wall, of the molded dielectric housing can provide an acoustic matching layer.

### CLAIM OF PRIORITY

This patent application claims the benefit of priority of Kellner, U.S. Provisional Patent Application No. 63/456,159, titled “ACOUSTIC TRANSDUCER ASSEMBLY WITH MOLDED INTERCONNECT DEVICE (MID),” filed on Mar. 31, 2023 (Attorney Docket No. 6409.249PRV), which is hereby incorporated by reference herein in its entirety.

### FIELD OF THE DISCLOSURE

This document pertains generally, but not by way of limitation, to non-destructive evaluation, and more particularly, to apparatus and techniques for providing an acoustic transducer assembly, such as an acoustic array, comprising a molded dielectric housing having metallization formed directly thereon.

### BACKGROUND

Non-destructive testing (NDT) can refer to use of one or more different techniques to inspect regions on or within an object, such as to ascertain whether flaws or defects exist, or to otherwise characterize the object being inspected. Examples of non-destructive test approaches can include use of an eddy-current testing approach where electromagnetic energy is applied to the object and resulting induced currents on or within the object are detected, with the values of a detected current (or a related impedance) providing an indication of the structure of the object under test, such as to indicate a presence of a crack, void, porosity, or other inhomogeneity.

Another approach for NDT can include use of an acoustic inspection technique, such as where one or more electroacoustic elements are used to insonify a region on or within the object under test, and acoustic energy that is scattered or reflected can be detected and processed. Such scattered or reflected energy can be referred to as an acoustic echo signal. Generally, such an acoustic inspection scheme involves use of acoustic frequencies in an ultrasonic range of frequencies, such as including pulses having energy in a specified range that can include value from, for example, a few hundred kilohertz, to tens of megahertz, as an illustrative example.

### SUMMARY OF THE DISCLOSURE

Acoustic testing, such as ultrasound-based inspection, can include focusing or beam-forming techniques to aid in construction of data plots or images representing a region of interest within the test specimen. Use of an array of ultrasound transducer elements can include use of a phased-array beamforming approach and can be referred to as Phased Array Ultrasound Testing (PAUT). For example, a delay-and-sum beamforming technique can be used such as including coherently summing time-domain representations of received acoustic signals from respective transducer elements or apertures. In another approach, a Total Focusing Method (TFM) beamforming technique can be used where one or more elements in an array (or apertures defined by such elements) are used to transmit an acoustic pulse and other elements are used to receive scattered or reflected acoustic energy, and a matrix is constructed of time-series (e.g., A-Scan) representations corresponding to a sequence of transmit-receive cycles in which the transmissions are occurring from different elements (or corresponding apertures) in the array. Such a TFM approach where A-scan data is obtained for each element in an array (or each defined aperture) can be referred to as a “full matrix capture” (FMC) technique.

Generally, an acoustic inspection instrument can be mated with a variety of different acoustic transducer assemblies in a modular manner. Accordingly, the shape and count of acoustic transducers associated with an acoustic transducer assembly can vary depending on the application. The present inventor has recognized, among other things, that design and fabrication of various different transducer assembly configurations can be simplified by use of fewer parts, such as facilitated by use of metallized interconnects formed directly on a dielectric material forming a housing of the transducer assembly. Approaches described herein are generally applicable to molded assembly where metallization is formed (e.g., plated) on specially activated regions of a polymer material. The metallization can be used to excite piezoelectric transducers or receive electrical signals therefrom. According to various examples herein, polymer material forming the housing also serves as an acoustic matching medium. Techniques such as direct printing or laser direct structuring can be used in a process to provide such metallization, and a metallized polymer structure formed in such a manner can generally be referred to as molded interconnect device (MID). Use of a molded interconnect fabrication approach can simplify an acoustic transducer assembly manufacturing process or provide a more robust transducer assembly, or both. In approaches where printing or laser activation (for laser direct structuring) are used to modify a surface in support of forming a metallization pattern, such a pattern can be varied easily to accommodate different piezoelectric element or housing configurations, providing manufacturing and configuration flexibility to accommodate different applications.

In an example, an acoustic transducer assembly for non-destructive test (NDT) can include a molded dielectric housing defining a cavity, a piezoelectric element located within the cavity, the piezoelectric element fixed to the dielectric housing and arranged to generate and receive acoustic energy coupled through the dielectric housing to and from an exterior face of the dielectric housing, conductive interconnections comprising metallization formed on an interior surface defined by the cavity, the conductive interconnections electrically coupled with respective regions of the piezoelectric element, and a backing material located within the cavity upon a surface of the piezoelectric element opposite a surface of the piezoelectric element fixed to the dielectric housing.

In an example, a method for fabricating an acoustic transducer assembly for non-destructive test (NDT) can include forming conductive interconnections comprising metallization on an interior surface of a cavity defined by a molded dielectric housing, and arranging a piezoelectric element within the cavity including fixing the piezoelectric element to the dielectric housing, the piezoelectric element arranged to generate and receive acoustic energy coupled through the dielectric housing to and from an exterior face of the dielectric housing and electrically coupling the conductive interconnections with respective regions of the piezoelectric element. The method can also include establishing a backing material within the cavity upon a surface of the piezoelectric element opposite a surface of the piezoelectric element fixed to the dielectric housing.

In an example, a method for fabricating an acoustic transducer assembly for non-destructive test (NDT) can include molding a dielectric housing defining a cavity, laser-activating respective regions of an unmachined surface of the dielectric housing in a pattern corresponding to conductive interconnections on an interior surface of the cavity, forming the conductive interconnections in the pattern by plating the laser-activated regions, and arranging a piezoelectric element within the cavity including fixing the piezoelectric element to the dielectric housing using an adhesive, the piezoelectric element arranged to generate and receive acoustic energy coupled through the dielectric housing to and from an exterior face of the dielectric housing and electrically coupling the conductive interconnections with respective regions of the piezoelectric element. The method can also include establishing a backing material within the cavity upon a surface of the piezoelectric element opposite a surface of the piezoelectric element fixed to the dielectric housing.

This summary is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example comprising an acoustic inspection system, such as can be used to perform at least a portion one or more techniques as shown and described herein.

FIG. 2A and FIG. 2B illustrate respective views of an A10-series acoustic inspection probe housing, such as can include metallization formed in a pattern to provide electrical interconnection to a piezoelectric element.

FIG. 3A, FIG. 3B, FIG. 3C, FIG. 3D, and FIG. 3E illustrate respective views of an A10-series acoustic inspection probe assembly process, such as can be processed to include a piezoelectric element, a backing material, a cap, and a cable assembly, such as to provide a multi-element acoustic inspection transducer assembly.

FIG. 4A and FIG. 4B illustrate respective views of a single-element cylindrical transducer assembly, showing the applicability of the approaches and materials described herein to other transducer assembly configurations.

FIG. 5A and FIG. 5B show views of a representative element and a representative spectrum for LCP VECTRA® 8401 polymer material forming a housing of an A10-series acoustic transducer assembly.

FIG. 5C and FIG. 5D show views of a representative element and a representative spectrum for PPA GF39 RENY™ polymer material forming a housing of an A10-series acoustic transducer assembly.

FIG. 5E and FIG. 5F show views of a representative element and a representative spectrum for PPA GF30 FORTII® 513 polymer material forming a housing of an A10-series acoustic transducer assembly.

FIG. 5G and FIG. 5H show views of a representative element and a representative spectrum for LCP TECACOMP® 1049426 polymer material forming a housing of an A10-series acoustic transducer assembly.

FIG. 5I and FIG. 5J show views of a representative element and a representative spectrum for an off-the-shelf A10-series acoustic transducer assembly not fabricated using the molded-interconnect-device approach described herein, for comparison.

FIG. 6 illustrates generally a technique, such as a fabrication method, comprising molding a dielectric housing comprising a cavity and forming associated metallization in a specified pattern on a surface of the dielectric housing.

### DETAILED DESCRIPTION

Acoustic transducer assemblies used for acoustic inspection are available in many different configurations, including different mechanical configurations, such as having a single element, multiple elements, angled-beam, and non-angled-beam configurations, or modular configurations such as can be mated with various coupling wedge configurations. Such transducer assemblies can vary in terms of specified center operating frequency, element count and size. Accordingly, manufacturers of such acoustic transducer assemblies can face a variety of challenges in maintaining inventory of components, tooling, and inventory of such assemblies, or varying a mix of different available assemblies in response to changing market needs. The present inventor has recognized, among other things, that a complexity of fabrication of an acoustic transducer assembly can be simplified, such as using an approach where conductive interconnections are formed on a molded dielectric housing. Such an approach can allow a reduction in assembly complexity of transducer assemblies, or rapid modification or shifting between different transducer assembly configurations, as illustrative examples. Such an approach can also enhance reliability, such as providing a more monolithic assembly where a wall or other portion of the dielectric housing can also serve as an acoustic matching layer. The materials and approaches described herein are generally applicable to single-element or multi-element acoustic transducer configurations, such as for non-destructive inspection applications.

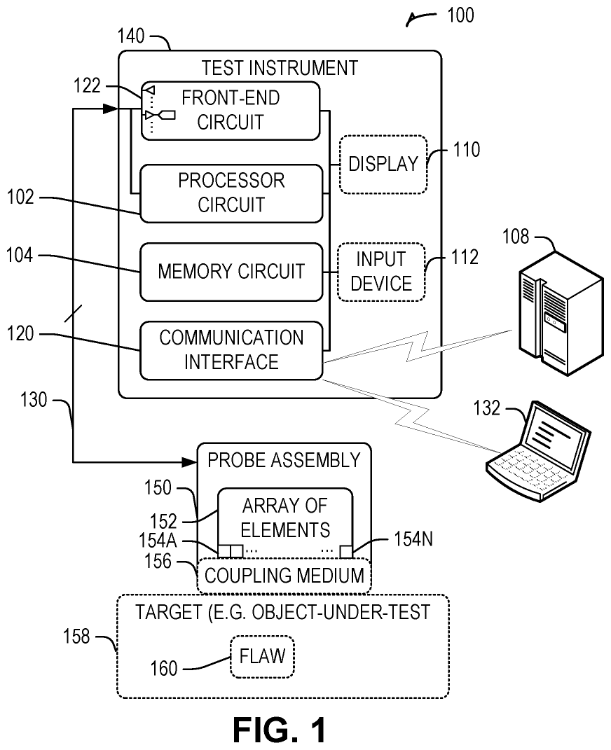

FIG. 1 illustrates generally an example comprising an acoustic inspection system 100, such as can be used to perform at least a portion one or more techniques as shown and described herein. The inspection system 100 can include a test instrument 140, such as a hand-held or portable assembly. The test instrument 140 can be electrically coupled to a probe assembly 150, such as using a multi-conductor interconnect 130. The probe assembly 150 can include one or more electroacoustic elements, such as an array 152 including respective elements 154A through 154N. The array 152 can follow a linear or curved contour or can include an array of elements extending in two axes, such as providing a matrix of transducer elements. Element size and pitch can be varied according to the inspection application.

A modular probe assembly 150 configuration can be used, such as to allow a test instrument 140 to be used with various different probe assemblies. Generally, the array 152 includes piezoelectric elements, such as can be acoustically coupled to a target 158 (e.g., a test specimen or “object-under-test”) through a coupling medium 156. The coupling medium can include a fluid or gel or a solid membrane (e.g., an elastomer or other polymer material), or a combination of fluid, gel, or solid structures. For example, an acoustic transducer assembly can include a transducer array coupled to a wedge structure comprising a rigid thermoset polymer having known acoustic propagation characteristics (for example, Rexolite® available from C-Lec Plastics Inc.), and water can be injected between the wedge and the structure under test as a coupling medium 156 during testing, or testing can be conducted with an interface between the probe assembly 150 and the target 158 otherwise immersed in a coupling medium.

The test instrument 140 can include digital and analog circuitry, such as a front-end circuit 122 including one or more transmit signal chains, receive signal chains, or switching circuitry (e.g., transmit/receive switching circuitry). The transmit signal chain can include amplifier and filter circuitry, such as to provide transmit pulses for delivery through an interconnect 130 to a probe assembly 150 for insonification of the target 158, such as to image or otherwise detect a flaw 160 on or within the target 158 structure by receiving scattered or reflected acoustic energy elicited in response to the insonification.

While FIG. 1 shows a single probe assembly 150 and a single array 152, other configurations can be used, such as multiple probe assemblies connected to a single test instrument 140, or multiple arrays 152 used with a single probe assembly 150 or multiple probe assemblies for pitch/catch inspection modes. Similarly, a test protocol can be performed using coordination between multiple test instruments 140, such as in response to an overall test scheme established from a master test instrument 140 or established by another remote system such as a compute facility 108 or general-purpose computing device such as a laptop 132, tablet, smart-phone, desktop computer, or the like. The test scheme may be established according to a published standard or regulatory requirement and may be performed upon initial fabrication or on a recurring basis for ongoing surveillance, as illustrative examples.

The receiver signal chain of the front-end circuit 122 can include one or more filters or amplifier circuits, along with an analog-to-digital conversion facility, such as to digitize echo signals received using the probe assembly 150. Digitization can be performed coherently, such as to provide multiple channels of digitized data aligned or referenced to each other in time or phase. The front-end circuit can be coupled to and controlled by one or more processor circuits, such as a processor circuit 102 included as a portion of the test instrument 140. The processor circuit can be coupled to a memory circuit 104, such as to execute instructions that cause the test instrument 140 to perform one or more of acoustic transmission, acoustic acquisition, processing, or storage of data relating to an acoustic inspection, or to otherwise perform techniques as shown and described herein. The test instrument 140 can be communicatively coupled to other portions of the system 100, such as using a wired or wireless communication interface 120.

For example, performance of one or more techniques as shown and described herein can be accomplished on-board the test instrument 140 or using other processing or storage facilities such as using a compute facility 108 or a general-purpose computing device such as a laptop 132, tablet, smart-phone, desktop computer, or the like. For example, processing tasks that would be undesirably slow if performed on-board the test instrument 140 or beyond the capabilities of the test instrument 140 can be performed remotely (e.g., on a separate system), such as in response to a request from the test instrument 140. Similarly, storage of imaging data or intermediate data such as A-scan matrices of time-series data or other representations of such data, for example, can be accomplished using remote facilities communicatively coupled to the test instrument 140. The test instrument can include a display 110, such as for presentation of configuration Information or results, and an input device 112 such as including one or more of a keyboard, trackball, function keys or soft keys, mouse-interface, touch-screen, stylus, or the like, for receiving operator commands, configuration information, or responses to queries.

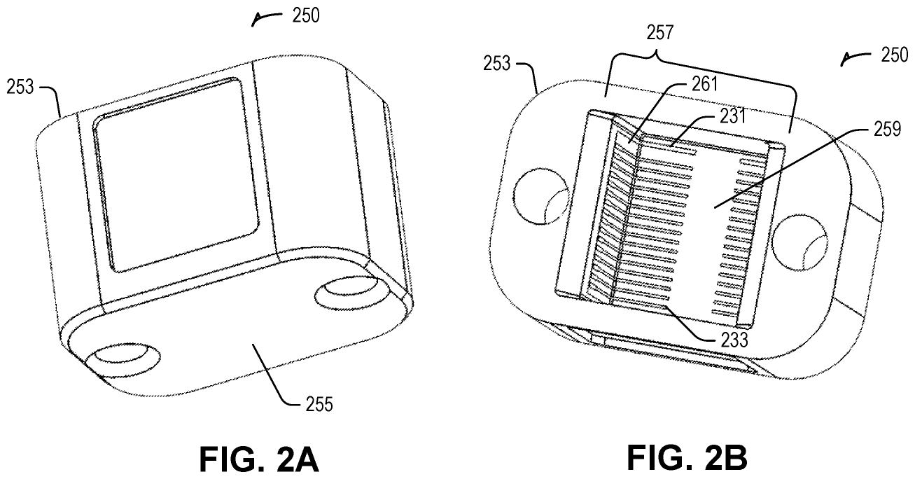

FIG. 2A and FIG. 2B illustrate respective views of a portion of an assembly similar to an A10-series acoustic inspection probe (Evident Scientific, Inc., MA, USA). A housing 253 can be formed, such as by injection molding a thermoplastic material. The housing 253 can define an active surface 255, such as to be placed in proximity to an object being inspected, or acoustically coupled to the object through a suitable coupling medium or wedge. The surface 255 can be a face of an acoustic matching layer formed by a bottom wall 259 of a cavity 257 of the housing 253.

Generally, in the approaches described in this document, the housing 253 can provide a base material upon which a metallization pattern defining the respective traces is formed. The cavity 257 can be formed during the injection molding process, and metallization can be formed in a pattern defining respective traces 231 and 233, such as extending along different surfaces of the cavity 257, such as along a portion of the bottom wall 259 and one or more side walls (e.g., side wall 261). Various approaches can be used to form such traces without requiring a separate printed circuit assembly (e.g., without requiring a separate rigid or flexible circuit assembly). A housing with such interconnects can be referred to as a molded interconnect device (MID). The metallization (such as corresponding to traces 231 and 233, for example) can allow for placement, soldering, and interconnection of electrical components, in a manner similar to a printed circuit board (PCB). However, unlike a PCB, an MID is not constrained to a planar configuration. Accordingly, such metallization can replace multiple components such as eliminating cabling or circuit board assemblies that might otherwise be needed to feed a piezoelectric element within the housing 253.

Laser direct structuring (LDS) is one approach that can be used to form a pattern for metallization. Another approach can include use of a two-shot injection molding process. LDS processing can be used with various different injection-moldable polymer compounds, where such compounds include a material that reacts (e.g., is modified) in response to laser treatment. Such laser treatment or “activation” of the surface can induce a localized roughness that will then accept copper plating using an electro-less copper plating process. The plated regions that have been laser-activated can then be further treated with other finishes, such as electro-less nickel plating and an immersion gold finish (e.g., “electro-less nickel/immersion gold,” referred to as ENIG). Other regions of the polymer that have not been laser activated remain un-plated. In this manner, complex masking or other operations are not required, and surfaces accepting metallization need not be planar, as mentioned above. Laser direct structuring after injection molding is one approach, and other approaches can include applying a suitable coating or paint that can be activated by laser in the regions to be metallized, at the cost of greater processing complexity and less flexibility with respect to feature shape, minimum size, and configuration of regions to be metallized.

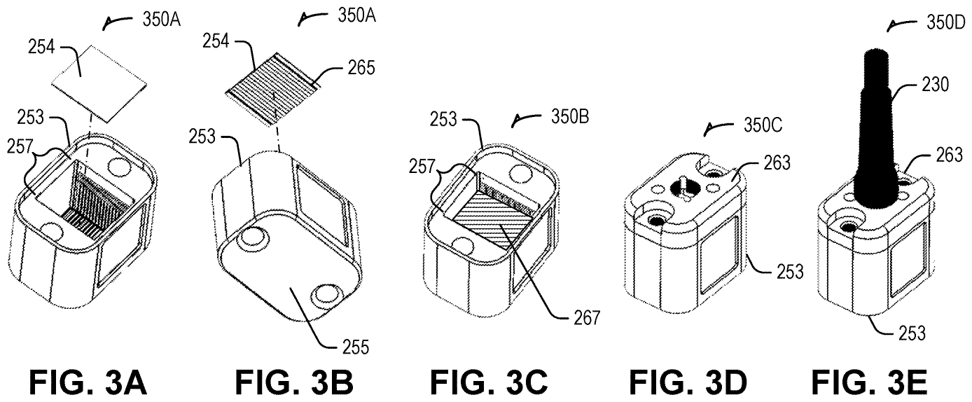

Generally, preparation of a housing 253 as shown in FIG. 2A and FIG. 2B includes injection molding of a thermoplastic material, with laser activation of regions where metallization is desired, followed by one or more plating steps. The present inventor has recognized, among other things, that the densities of polymers that are generally compatible with LDS processing and additives can make them suitable for use as an acoustic matching layer in a phased-array acoustic transducer assembly 250. The cavity 257 (also referred to as a bucket) can provide a surface for traces to contact a piezoelectric element (e.g., a piezoelectric composite material) as shown in FIG. 3A and FIG. 3B, amongst others. The acoustic matching layer can be tuned by lapping or otherwise machining (e.g., grinding) the surface 255 to provide a specified thickness of the bottom wall 259, as discussed below, in consideration of center operating frequency and dielectric material properties (e.g., density, acoustic propagation velocity, and corresponding acoustic impedance versus frequency).

Materials and processing parameters suitable for laser direct structuring are available from, for example, LPKF Laser & Electronics AG (Germany). Harder polymer material classes that are suitable for industrial acoustic inspection applications are liquid crystal polymer (LCP) and polyether ether ketone (PEEK), as illustrative examples. Softer materials can include PA6/6 and polyphthalamide (PPA), as illustrative examples. Such materials are generally available in pelletized form, such as for 2-component injection molding or hot stamping. For LDS processing, injection molded materials are generally unmachined before metallization, at least in the regions at or near where metallization is to be formed. Machining or other mechanical modification of injection-molded structures can induce surface roughening that results in plating adhesion in areas other than the desired metallization area. Generally, as discussed below, higher density materials offer a more optimal acoustic impedance (ZL).

FIG. 3A, FIG. 3B, FIG. 3C, FIG. 3D, and FIG. 3E illustrate respective views of an A10-series acoustic inspection probe assembly at various stages of processing, such as can be processed to include a piezoelectric element, a backing material, a cap, and a cable assembly. This assembly process can provide a multi-element acoustic inspection transducer assembly. In the example herein, the A10-series probe assembly corresponds generally to a 5L16-A10 phased array assembly available from Evident Scientific, Inc., operating with an acoustic center frequency of about 5 megahertz (MHz), and having 16 elements defining an array. This illustrative (but non-limiting) example was selected for evaluation being representative of a mid-frequency, linear configuration. Generally, the use of the A10 configurations in this document is merely one example of probe assembly shape, and the subject matter herein is applicable to other probe geometries.

In FIG. 3A and FIG. 3B, a portion of a probe assembly 350A is shown having metallization formed in a cavity 257 of housing 253. The housing 253 naturally defines a bucket region (e.g., cavity 257) into which a piezoelectric element can be located and bonded. For example, the piezoelectric element can be a scribed piezoelectric composite assembly 254 defining respective piezoelectric material regions 265 forming an array, such as shown in FIG. 3A and FIG. 3B. The scribed piezoelectric composite assembly 254 can include a conductive layer and a piezoelectric material layer, such as having the piezoelectric material layer divided into respective regions by scribing or by other means to create respective isolated piezoelectric material regions that can be coupled together on one face using a conductive bus layer or trace. The scribed piezoelectric composite assembly 254 can be mechanically fixed (e.g., bonded or otherwise anchored) within the cavity using an epoxy. The epoxy need not be conductive, avoiding a need for a fine screen or dispense pattern. Fine microstructure of the metallized regions in the cavity 257 (such as formed using laser direct structuring and plating as discussed elsewhere) can protrude through the epoxy bonding material to electrically couple with corresponding portions of the scribed piezoelectric composite assembly 254 to provide interconnections for addressing an array defined by the scribed piezoelectric composite assembly 254. For example, such metallization can define a reference (e.g., “ground”) node or “bus,” and corresponding individual element conductors, such as forming pads that mate with corresponding portions of the scribed piezoelectric composite assembly 254 to provide addressability of individual regions in the array.

Referring to FIG. 3B, the probe assembly 350A can define an acoustic matching layer between the scribed piezoelectric composite assembly 254 and the surface 255. For example, as discussed below, housing 253 can be ground or lapped at the surface 255 to establish a face thickness corresponding to a center acoustic operating frequency and acoustic impedance of the dielectric material forming the housing 253. In this manner, a piezoelectric element located within the cavity 257 is arranged to generate or receive acoustic energy coupled through the dielectric housing 253 to or from an exterior face (e.g., surface 255) of the dielectric housing 253.

Referring to FIG. 3C, the probe assembly 350B can have a backing material 267 located in the cavity 257. The backing material 267 can either be injected in liquid form such as curing within the cavity 257 (e.g., cast in a manner similar to potting material), or the backing material 267 can be formed from one or more blocks of material, such as bonded to a surface of the scribed piezoelectric composite assembly 254 opposite the bottom-facing surface of the cavity 257, such as prior to wiring or capping the probe assembly 350B. If a cast backing material 267 is used, such material need not be inserted at FIG. 3C and could instead be injected through one or more apertures in the assembly 350C or 350D after subsequent operations such as after electrically bonding cabling to the metallization and applying a cap as shown in FIG. 3D and FIG. 3E.

Referring to FIG. 3D, the probe assembly 350C can have a cap 263 affixed, such as before or after connecting individual wires or other conductors to the metallization formed on an interior wall of the housing 253. For example, the cap could include a connector for affixing a cable. As mentioned above, connecting wires or other conductors and applying the cap 263 can occur before or after backing material 267 is present. At FIG. 3E, the probe assembly 350D can have a cable assembly 230 present, such as mechanically coupled with the cap 263. If the cap is not connectorized, the cable assembly 230 and cap 263 can be integrated together, and connections can be formed between respective conductors in the cable and pads defined by metallization on the sidewalls of the cavity 257 as shown in FIG. 3C, for example. The cap 263 can be affixed to the housing 253 using adhesive or otherwise mechanically fixed using fasteners such as screws.

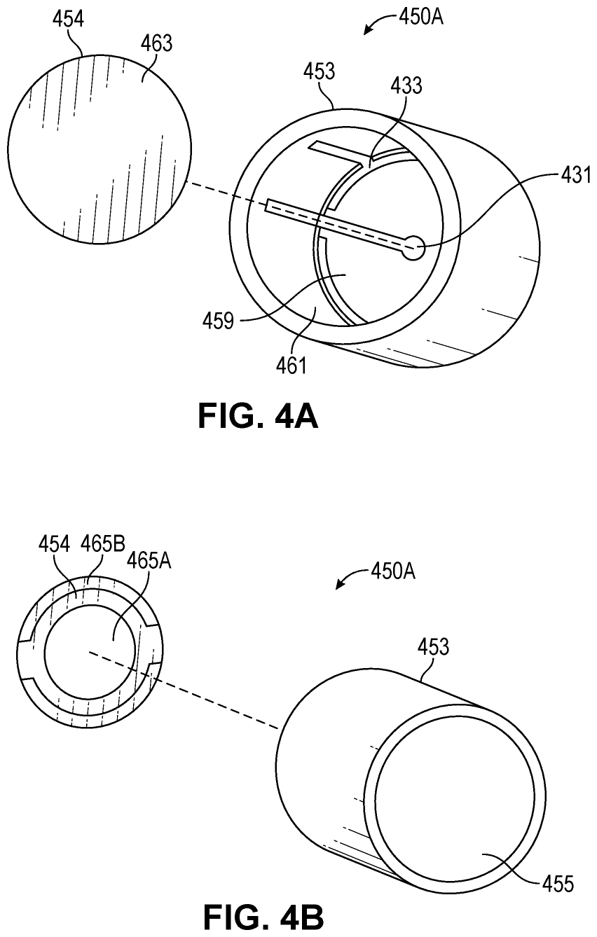

The configuration shown in the examples above comprises a multi-element piezoelectric composite (e.g., for phased array application) and associated housing. The techniques herein are applicable to other transducer configurations, such as single-element (e.g., cylindrical) assemblies. FIG. 4A and FIG. 4B illustrate respective views of a single-element cylindrical transducer assembly 450A, showing the applicability of the approaches and materials described herein to other transducer assembly configurations. As shown in FIG. 4A and FIG. 4B, a piezoelectric element (e.g., a composite 454 having a conductive layer 465) can be placed in a cylindrical cavity defined by a dielectric housing 453. As in other examples described herein, metallization can be formed in a specified pattern, such as using laser direct structuring and electroless plating, to establish a first trace 431 and a second trace 433. The first trace 431 and the second trace 433 can extend along a bottom surface 459 and up an inner wall 461 of the dielectric housing 453. Referring to FIG. 4B, the composite 454 can include conductive layers 465B and 465A. For example, the layer 465B can extend along the side of the composite 454 to provide a connection to the layer 465 on the opposite surface of the composite 454, and the layer 465A can provide another terminal, forming a unimorph single-element configuration. A backing material, cap, and cabling can be added as in other examples described herein. For example, a thickness of a wall of the dielectric housing 453 single-element cylindrical transducer assembly 450A defining an active surface 455 can be specified in order to provide an acoustic matching layer at a specified center frequency of operation of the single-element cylindrical transducer assembly 450A.

The selection of a dielectric material for the housing in the examples described in this document is not restricted to considerations of compatibility with LDS or other similar processing. Acoustic properties of the dielectric material also impact performance for acoustic transducer assembly applications. Generally, acoustic impedance is not characterized or available in material vendor data sheets associated with general-purpose injection-moldable polymer materials, and other related parameters such as acoustic propagation velocity are also not characterized. The present inventor has recognized, among other things, that density data can provide useful guidance as to suitability of materials for acoustic applications. Many polymer materials can be characterized as “high speed” materials for acoustic propagation purposes, however, their associated acoustic propagation velocity is still less than is typical for a thermocarbon-composition matching layer. One indication of potential suitability is a density at or near 2 grams per cubic centimeter (g/cm³), or more. Many materials that are approved for LDS processing have densities below such a threshold. An unexpected result identified by the inventor is that such materials still exhibit acceptable acoustic performance when used for a housing having an integrated matching layer made from the same material as the housing (e.g., formed by a wall of the housing). As an illustrative example, the following four materials were evaluated, and their associated densities are listed:

TABLE I
Dielectric Housing Materials and Associated Densities

| | |
|---|---|
| PPA GF39 RENY ™ XHP 1002 (Mitsubishi Engineering | 1.47 g/cm³ |
| Plastics) | |
| PPA GF30 FORTII ® 513 (DSM) | 1.58 g/cm³ |
| LCP TECACOMP ® 1049426 (Ensinger) | 1.74 g/cm³ |
| LCP VECTRA ® 840I LDS (Celanese) | 1.81 g/cm³ |

Velocity measurements were obtained by measuring time of flight through two different thicknesses of each of the materials listed above in TABLE I. Time-of-flight measurements along with the published density data can be used to determine a corresponding acoustic impedance (Z) of each material. Such an acoustic impedance can then be used to determine a nominal thickness for each material as a quarter-wavelength matching layer, for different specified center frequencies.

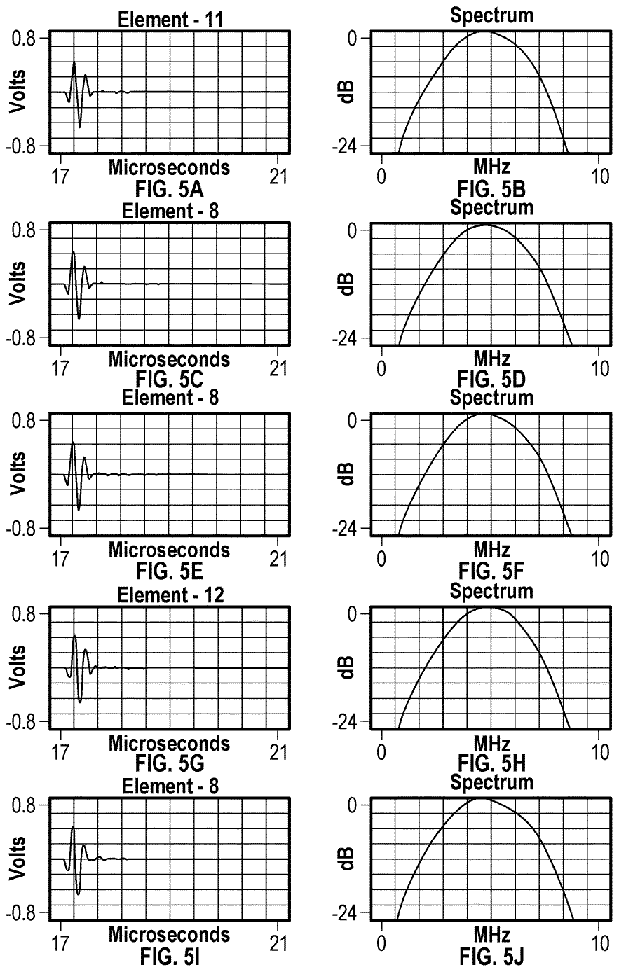

FIG. 5A and FIG. 5B show views of a representative element and a representative spectrum for LCP VECTRA® 8401 polymer material forming a housing of an A10-series acoustic transducer assembly. FIG. 5C and FIG. 5D show views of a representative element and a representative spectrum for PPA GF39 RENY™ polymer material forming a housing of an A10-series acoustic transducer assembly. FIG. 5E and FIG. 5F show views of a representative element and a representative spectrum for PPA GF30 FORTII® 513 polymer material forming a housing of an A10-series acoustic transducer assembly. FIG. 5G and FIG. 5H show views of a representative element and a representative spectrum for LCP TECACOMP® 1049426 polymer material forming a housing of an A10-series acoustic transducer assembly. FIG. 5I and FIG. 5J show views of a representative element and a representative spectrum for an off-the-shelf A10-series acoustic transducer assembly not fabricated using the molded-interconnect-device approach described herein, for comparison. As shown by the experimentally-obtained results above, bandwidth, impulse response, and center frequency show good agreement between the standard material configuration of FIG. 5I and FIG. 5J versus the simplified configuration using molded-interconnect-device fabrication.

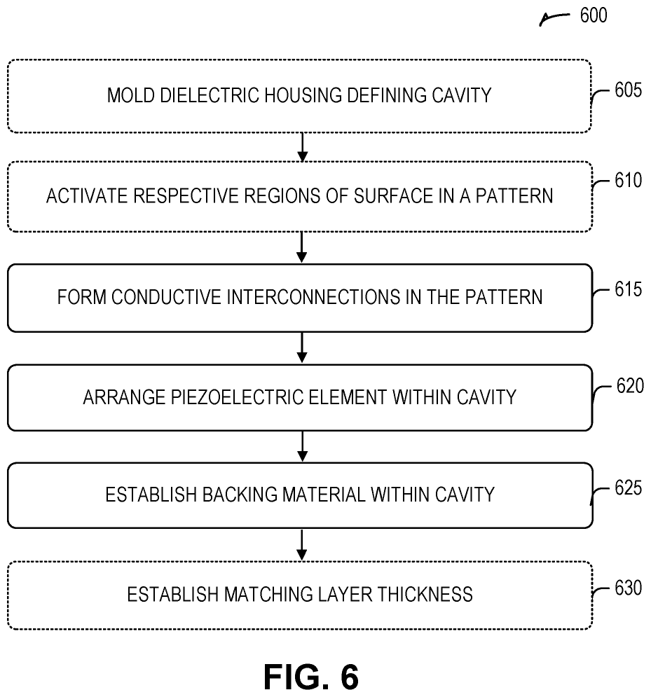

FIG. 6 illustrates generally a technique 600, such as a fabrication method, comprising molding a dielectric housing comprising a cavity and forming associated metallization in a specified pattern on a surface of the dielectric housing. At 605, a dielectric housing can be molded, where the dielectric housing defines a cavity. Such molding can include an injection molding process where the cavity is not machined prior to downstream processing. At 610, respective regions of a surface of the dielectric housing can be activated, such as ablated or otherwise treated to create roughened regions that will accept plating (e.g., for plating using an electro-less plating process). At 615, conductive regions patterned at 610 can be formed, such as using immersion of the dielectric housing (or a portion thereof) in a plating bath. For example, plating operations can include an initial copper plating operation, followed by nickel and gold plating operations to provide traces and corresponding connection pads conforming to an interior surface of the dielectric housing, in a manner that would otherwise be impractical. At 620, a piezoelectric element, such as single element or multi-element array can be arranged within a cavity defined by the dielectric housing (e.g., fixed to the dielectric housing), and at 625, a backing material can be located within the cavity. As discussed above, the backing material can be cast (such as after interconnections to cabling are made and a cap is attached), or a solid mass of backing material can be inserted in the cavity. At 630, if a portion of the dielectric housing is serving as an acoustic matching layer, a specified matching layer thickness can be established, such as by machining a face of the dielectric housing after formation of conductive interconnections. Machining at this later phase of fabrication does not preclude earlier formation of metallization using LDS and associated plating.

### VARIOUS NOTES

In Example 1, an acoustic transducer assembly for non-destructive test (NDT) comprises a molded dielectric housing defining a cavity, a piezoelectric element located within the cavity, the piezoelectric element fixed to the dielectric housing and arranged to generate and receive acoustic energy coupled through the dielectric housing to and from an exterior face of the dielectric housing, conductive interconnections comprising metallization formed on an interior surface defined by the cavity, the conductive interconnections electrically coupled with respective regions of the piezoelectric element, and a backing material located within the cavity upon a surface of the piezoelectric element opposite a surface of the piezoelectric element fixed to the dielectric housing.

In Example 2, the piezoelectric element comprises a piezoelectric material and a conductive layer.

In Example 3, the piezoelectric material of Example 1 or Example 2 comprises an array of piezoelectric material regions on the conductive layer, and the respective conductive interconnections provide electrical addressability of respective piezoelectric material regions defining the array.

In Example 4, the acoustic transducer assembly of any of Examples 1 through 3 includes a portion of the dielectric housing between the exterior face and the piezoelectric element that is configured as an acoustic matching layer having a specified thickness of a dielectric material comprising the dielectric housing.

In Example 5, the acoustic transducer assembly of any of Examples 1 through 4 includes that the cavity is unmachined after molding of the dielectric housing.

In Example 6, the acoustic transducer assembly of any of Examples 1 through 5 includes that the metallization comprises copper.

In Example 7, the acoustic transducer assembly of any of Examples 1 through 6 includes that the metallization comprises a gold surface upon an intermediate layer of nickel between the gold surface and copper.

In Example 8, the acoustic transducer assembly of Example 7 includes that the nickel intermediate layer and gold surface comprises an electro-less-nickel immersion-gold (ENIG) plating.

In Example 9, the acoustic transducer assembly of any of Examples 1 through 8 comprises a cap assembly mechanically coupled to the dielectric housing, the cap assembly comprising or supporting a multi-conductor cable, the multi-conductor cable comprising respective conductors that are electrically coupled with the respective conductive interconnections formed on the interior surface defined by the cavity of the dielectric housing.

In Example 10, a method for fabricating an acoustic transducer assembly for non-destructive test (NDT) comprises forming conductive interconnections comprising metallization on an interior surface of a cavity defined by a molded dielectric housing, arranging a piezoelectric element within the cavity including fixing the piezoelectric element to the dielectric housing, the piezoelectric element arranged to generate and receive acoustic energy coupled through the dielectric housing to and from an exterior face of the dielectric housing and electrically coupling the conductive interconnections with respective regions of the piezoelectric element, and the method comprises establishing a backing material within the cavity upon a surface of the piezoelectric element opposite a surface of the piezoelectric element fixed to the dielectric housing.

In Example 11, the method of Example 10 comprises injection molding the dielectric housing.

In Example 12, the method of any of Examples 10 or 11 includes that a portion of the dielectric housing between the exterior face and the piezoelectric element is configured as an acoustic matching layer having a specified thickness of a dielectric material comprising the dielectric housing, the method comprises establishing the specified thickness by machining an injection molded portion of the dielectric housing including planarizing the exterior face.

In Example 13, the method of any of Examples 10 through 12 includes that the forming the respective conductive interconnections comprises modifying respective regions of an unmachined surface of the dielectric housing in a pattern corresponding to the respective conductive interconnections.

In Example 14, the method of Example 13 includes that the modifying the unmachined surface comprises laser activating the respective regions of the unmachined surface in the pattern corresponding to the respective conductive interconnections.

In Example 15, the method of Example 14 includes that the forming the respective conductive interconnections comprises plating laser-activated regions with copper.

In Example 16, the method of Example 15 includes that the forming the respective conductive interconnections comprises forming a gold surface upon an intermediate layer of nickel between the gold surface and the copper.

In Example 17, the method of Example 16 includes that the respective conductive interconnections comprise electro-less-nickel immersion-gold (ENIG) plating.

In Example 18, the method of any of Examples 10 through 17 comprises mechanically coupling a cap assembly to the dielectric housing, the cap assembly comprising or supporting a multi-conductor cable, the multi-conductor cable comprising respective conductors that are electrically coupled with the respective conductive interconnections formed on the interior surface defined by the cavity of the dielectric housing.

In Example 19, the method of Example 18 includes that the establishing the backing material includes casting the backing material through an aperture in either the dielectric housing or the cap.

In Example 20, a method for fabricating an acoustic transducer assembly for non-destructive test (NDT) comprises molding a dielectric housing defining a cavity, laser-activating respective regions of an unmachined surface of the dielectric housing in a pattern corresponding to conductive interconnections on an interior surface of the cavity, forming the conductive interconnections in the pattern by plating the laser-activated regions, arranging a piezoelectric element within the cavity including fixing the piezoelectric element to the dielectric housing using an adhesive, the piezoelectric element arranged to generate and receive acoustic energy coupled through the dielectric housing to and from an exterior face of the dielectric housing and electrically coupling the conductive interconnections with respective regions of the piezoelectric element, and the method comprises establishing a backing material within the cavity upon a surface of the piezoelectric element opposite a surface of the piezoelectric element fixed to the dielectric housing.

Each of the non-limiting aspects above can stand on its own or can be combined in various permutations or combinations with one or more of the other aspects or other subject matter described in this document.

The above detailed description includes references to the accompanying drawings, which form a part of the detailed description. The drawings show, by way of illustration, specific embodiments in which the invention can be practiced. These embodiments are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc., are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An acoustic transducer assembly for non-destructive test (NDT), the acoustic transducer assembly comprising:
a molded dielectric housing defining a cavity;
a piezoelectric element located within the cavity, the piezoelectric element fixed to the dielectric housing and arranged to generate and receive acoustic energy coupled through the dielectric housing to and from an exterior face of the dielectric housing;
conductive interconnections comprising metallization formed on an interior surface defined by the cavity, the conductive interconnections electrically coupled with respective regions of the piezoelectric element; and
a backing material located within the cavity upon a surface of the piezoelectric element opposite a surface of the piezoelectric element fixed to the dielectric housing.

2. The acoustic transducer assembly of claim 1, wherein the piezoelectric element comprises a piezoelectric material and a conductive layer.

3. The acoustic transducer assembly of claim 2, wherein the piezoelectric material comprises an array of piezoelectric material regions on the conductive layer; and
wherein the respective conductive interconnections provide electrical addressability of respective piezoelectric material regions defining the array.

4. The acoustic transducer assembly of claim 1, wherein a portion of the dielectric housing between the exterior face and the piezoelectric element is configured as an acoustic matching layer having a specified thickness of a dielectric material comprising the dielectric housing.

5. The acoustic transducer assembly of claim 1, wherein the cavity is unmachined after molding of the dielectric housing.

6. The acoustic transducer assembly of claim 1, wherein the metallization comprises copper.

7. The acoustic transducer assembly of claim 6, wherein the metallization comprises a gold surface upon an intermediate layer of nickel between the gold surface and the copper.

8. The acoustic transducer assembly of claim 7, wherein the nickel intermediate layer and gold surface comprises an electro-less-nickel immersion-gold (ENIG) plating.

9. The acoustic transducer assembly of claim 1, comprising a cap assembly mechanically coupled to the dielectric housing, the cap assembly comprising or supporting a multi-conductor cable, the multi-conductor cable comprising respective conductors that are electrically coupled with the respective conductive interconnections formed on the interior surface defined by the cavity of the dielectric housing.

10. A method for fabricating an acoustic transducer assembly for non-destructive test (NDT), the method comprising:
forming conductive interconnections comprising metallization on an interior surface of a cavity defined by a molded dielectric housing;
arranging a piezoelectric element within the cavity including:
fixing the piezoelectric element to the dielectric housing, the piezoelectric element arranged to generate and receive acoustic energy coupled through the dielectric housing to and from an exterior face of the dielectric housing; and
electrically coupling the conductive interconnections with respective regions of the piezoelectric element; and
establishing a backing material within the cavity upon a surface of the piezoelectric element opposite a surface of the piezoelectric element fixed to the dielectric housing.

11. The method of claim 10, comprising injection molding the dielectric housing.

12. The method of claim 10, wherein a portion of the dielectric housing between the exterior face and the piezoelectric element is configured as an acoustic matching layer having a specified thickness of a dielectric material comprising the dielectric housing; and
wherein the method comprises establishing the specified thickness by machining an injection molded portion of the dielectric housing including planarizing the exterior face.

13. The method of claim 11, wherein forming the respective conductive interconnections comprises modifying respective regions of an unmachined surface of the dielectric housing in a pattern corresponding to the respective conductive interconnections.

14. The method of claim 13, wherein the modifying the unmachined surface comprises laser activating the respective regions of the unmachined surface in the pattern corresponding to the respective conductive interconnections.

15. The method of claim 14, wherein forming the respective conductive interconnections comprises plating laser-activated regions with copper.

16. The method of claim 15, wherein forming the respective conductive interconnections comprises forming a gold surface upon an intermediate layer of nickel between the gold surface and the copper.

17. The method of claim 16, wherein forming the respective conductive interconnections comprises electro-less-nickel immersion-gold (ENIG) plating.

18. The method of claim 10, comprising mechanically coupling a cap assembly to the dielectric housing, the cap assembly comprising or supporting a multi-conductor cable, the multi-conductor cable comprising respective conductors that are electrically coupled with the respective conductive interconnections formed on the interior surface defined by the cavity of the dielectric housing.

19. The method of claim 18, wherein establishing the backing material includes casting the backing material through an aperture in either the dielectric housing or the cap.

20. A method for fabricating an acoustic transducer assembly for non-destructive test (NDT), the method comprising:
molding a dielectric housing defining a cavity;
laser-activating respective regions of an unmachined surface of the dielectric housing in a pattern corresponding to conductive interconnections on an interior surface of the cavity;
forming the conductive interconnections in the pattern by plating the laser-activated regions;
arranging a piezoelectric element within the cavity including:
fixing the piezoelectric element to the dielectric housing using an adhesive, the piezoelectric element arranged to generate and receive acoustic energy coupled through the dielectric housing to and from an exterior face of the dielectric housing; and
electrically coupling the conductive interconnections with respective regions of the piezoelectric element; and
establishing a backing material within the cavity upon a surface of the piezoelectric element opposite a surface of the piezoelectric element fixed to the dielectric housing.
